(19) United States
(12) Patent Application Publication
(10) Pub. No.: US 2024/0179876 A1
(43) Pub. Date: May 30, 2024

(54) MULTI-SPLIT AIR-CONDITIONING SYSTEM AND METHOD FOR AIR CONDITIONING

(71) Applicant: Hebei Qinhuai Data Co., Limited., Zhangjiakou City (CN)

(72) Inventors: Binghua ZHANG, Zhangjiakou City (CN); Mingjiang LI, Zhangjiakou City (CN); Shun WANG, Zhangjiakou City (CN)

(21) Appl. No.: 18/510,543

(22) Filed: Nov. 15, 2023

(30) Foreign Application Priority Data
Nov. 30, 2022 (CN) 202211524549.1

(51) Int. Cl. H05K 7/20; F24F 1/0003; F24F 11/84

(52) U.S. Cl. CPC H05K 7/20745; F24F 1/0003; F24F 11/84

(57) ABSTRACT

Embodiments of the present disclosure provide a multi-split air-conditioning system and a method for air conditioning. The system includes a cold source module, a pump driving module and an indoor module connected to a loop through a pipeline, where the cold source module includes a plurality of cold source submodules. Outlet pipelines of the plurality of cold source submodules are connected to an inlet pipeline of the pump driving module. The indoor module includes a plurality of indoor terminals. An outlet pipeline of the pump driving module is connected to inlet pipelines of the plurality of indoor terminals. Outlet pipelines of the plurality of indoor terminals converge and merge, and then are connected to an inlet pipeline of the cold source module.

### CROSS REFERENCE TO RELATED APPLICATION

This application claims priority to Chinese Patent Application No. 202211524549.1, titled “MULTI-SPLIT AIR-CONDITIONING SYSTEM AND METHOD FOR AIR CONDITIONING”, and filed to the China National Intellectual Property Administration on Nov. 30, 2022, the entire contents of which are incorporated herein by reference.

### TECHNICAL FIELD

The present disclosure relates to the field of air conditioning technology, and more particularly, to a multi-split air-conditioning system and a method for air conditioning.

### BACKGROUND

In recent years, data centers have developed towards high power density, and quantity of heat produced by computer devices in computer rooms has been continuously increasing. In data center computer rooms, generally problems of heat dissipation are solved by means of mechanical refrigeration. However, the mechanical refrigeration consumes a large amount of electrical energy, accounting for a larger proportion of total electric power consumption in the data centers.

At present, in large data centers, air-conditioning systems including chilled water units may be employed to dissipate heat. In some cases, limitations in sites and high energy efficiency make it impossible to use the chilled water units.

### SUMMARY

To solve some or all of problems existing in the existing technologies, embodiments of the present disclosure provide a multi-split air-conditioning system and a method for air conditioning. The technical solutions are as follows.

In a first aspect, there is provided a multi-split air-conditioning system, which includes a cold source module, a pump driving module and an indoor module connected to a loop through a pipeline.

The cold source module includes a plurality of cold source submodules, where outlet pipelines of the plurality of cold source submodules are connected to an inlet pipeline of the pump driving module.

The indoor module includes a plurality of indoor terminals; an outlet pipeline of the pump driving module is connected to inlet pipelines of the plurality of indoor terminals; and outlet pipelines of the plurality of indoor terminals converge and merge, and then are connected to an inlet pipeline of the cold source module.

Alternatively, the outlet pipelines of the plurality of cold source submodules converge and merge, and then are connected to the inlet pipeline of the pump driving module.

Alternatively, each of the plurality of cold source submodules includes: a compressor, a first condenser, a second condenser, a heat exchanger, a first solenoid valve, a second solenoid valve, a third solenoid valve, and a compressor.

An inlet of the compressor is connected to a first outlet pipeline of the heat exchanger, and an outlet of the compressor is connected to an inlet pipeline of the first condenser and/or an inlet pipeline of the second condenser.

An outlet of the first condenser is connected to a first inlet pipeline of the heat exchanger, and an outlet of the second condenser is connected to the first inlet pipeline of the heat exchanger and/or the inlet pipeline of the pump driving module.

The first solenoid valve is arranged on a second inlet pipeline of the heat exchanger or a second outlet pipeline of the heat exchanger.

The second solenoid valve is arranged between the indoor module and the second condenser, and/or arranged between the second condenser and the pump driving module.

The third solenoid valve is arranged between the compressor and the second condenser, and/or arranged between the second condenser and the heat exchanger.

The second outlet pipeline of the heat exchanger is connected to the pump driving module.

Alternatively, an electric regulating ball valve is connected to a second inlet pipeline of the heat exchanger or a second outlet pipeline of the heat exchanger.

Alternatively, an electronic expansion valve is connected to a first inlet pipeline of the heat exchanger.

Alternatively, the pump driving module includes a refrigerant pump and a fluid reservoir.

Alternatively, the pump driving module also includes a check valve connected to the refrigerant pump through a pipeline.

In a second aspect, there is provided a method for air conditioning in a data center computer room, and the method is applied to the multi-split air-conditioning system in the first aspect. The method includes:
switching a refrigeration mode by turning on or off the first solenoid valve, the second solenoid valve and the third solenoid valve, where the refrigeration mode includes a mechanical refrigeration mode, a natural refrigeration mode, and a hybrid refrigeration mode.

Alternatively, the natural refrigeration mode is enabled when the first solenoid valve is turned off.

Alternatively, the hybrid refrigeration mode is enabled when the first solenoid valve and the second solenoid valve are turned on and the third solenoid valve is turned off.

Alternatively, the mechanical refrigeration mode is enabled when the first solenoid valve and the third solenoid valve are turned on and the second solenoid valve is turned off.

Alternatively, a ratio of mechanical refrigeration capacity to natural refrigeration capacity is adjusted by adjusting an opening degree of the electric regulating ball valve.

By adopting the present disclosure, at least following technical effects can be achieved.

By splicing and combining the plurality of cold source submodules, it is easy to expand the air-conditioning system, which can achieve greater refrigeration demands. Moreover, the plurality of cold source submodules share the pump driving module, which can save space, reduce construction costs, and improve energy efficiency of the air-conditioning system. Further, by turning on or off the first solenoid valve, the second solenoid valve and the third solenoid valve, flexible switching of the refrigeration modes may be achieved. On or off of the second solenoid valve and on or off of the third solenoid valve are mutually exclusive, which may allow the second condenser to be used as a condenser of a secondary-side system in the natural refrigeration mode and as a condenser of a primary-side compressor system in the mechanical refrigeration mode. This can effectively reduce a resistance of a condenser fan and reduce device costs. In the hybrid refrigeration mode, by adjusting the opening degree of the electric regulating ball valve, a flow rate of a refrigerant flowing through the heat exchanger in the secondary-side system in the mechanical refrigeration mode may be adjusted, that is, the ratio of the mechanical refrigeration capacity to the natural refrigeration capacity may be adjusted, to achieve stepless adjustment of the hybrid refrigeration where the natural refrigeration mode and the mechanical refrigeration mode coexist, thereby maximizing the energy efficiency of the entire air-conditioning system.

### BRIEF DESCRIPTION OF THE DRAWINGS

To describe the technical solutions of the embodiments of the present disclosure more clearly, the accompanying drawings required for describing the embodiments will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is a schematic structural diagram of a multi-split air-conditioning system according to an embodiment of the present disclosure;

FIG. 2 is a schematic structural diagram of another multi-split air-conditioning system according to an embodiment of the present disclosure;

FIG. 3 is a schematic structural diagram of a pump driving module according to an embodiment of the present disclosure;

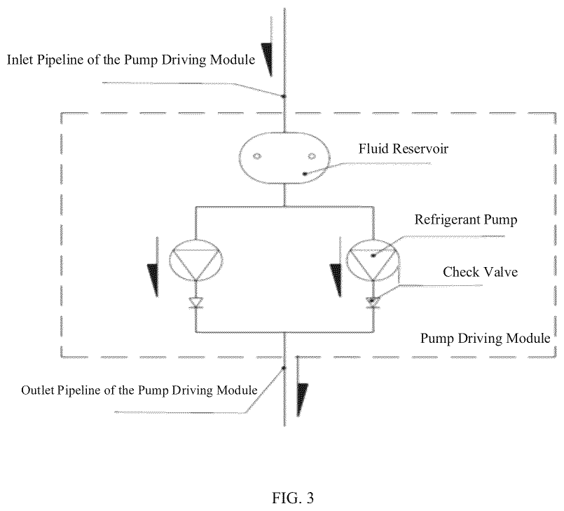

FIG. 4 is a schematic structural diagram of a cold source submodule according to an embodiment of the present disclosure;

FIG. 5 is a schematic structural diagram of another cold source submodule according to an embodiment of the present disclosure;

FIG. 6 is a schematic structural diagram of yet another cold source submodule according to an embodiment of the present disclosure; and

FIG. 7 is a schematic structural diagram of still another cold source submodule according to an embodiment of the present disclosure.

### DETAILED DESCRIPTION

To make the objectives, technical solutions and advantages of the present disclosure clearer, the embodiments of the present disclosure will be further described below in detail with reference to the accompanying drawings. Terms such as “upper”, “above”, “lower”, “below”, “first end”, “second end”, “one end”, “other end” and the like as used herein, which denote spatial relative positions, describe the relationship of one unit or feature relative to another unit or feature in the accompanying drawings for the purpose of illustration. The terms of the spatial relative positions may be intended to include different orientations of the device in use or operation other than the orientations shown in the accompanying drawings. For example, the units that are described as “below” or “under” other units or features will be “above” other units or features if the device in the accompanying drawings is turned upside down. Thus, the exemplary term “below” can encompass both the orientations of above and below. The device may be otherwise oriented (rotated by 90 degrees or facing other directions) and the space-related descriptors used herein are interpreted accordingly.

In addition, the terms “installed”, “arranged”, “provided”, “connected”, “slidably connected”, “fixed” and “sleeved” should be understood in a broad sense. For example, the “connection” may be a fixed connection, a detachable connection or integrated connection, a mechanical connection or an electrical connection, a direct connection or indirect connection by means of an intermediary, or an internal connection between two apparatuses, components or constituent parts. For those of ordinary skill in the art, concrete meanings of the above terms in the present disclosure may be understood based on concrete circumstances.

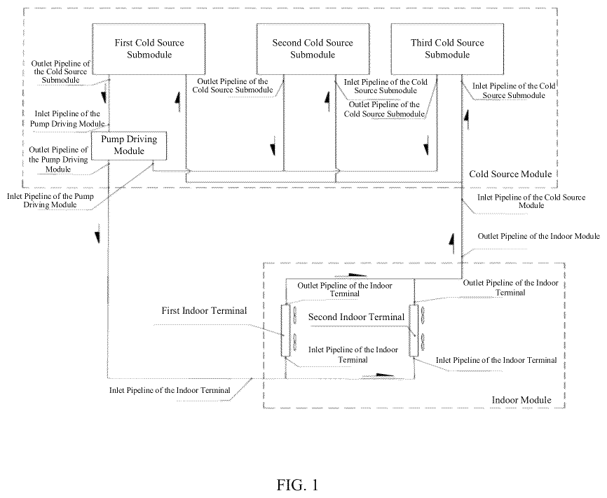

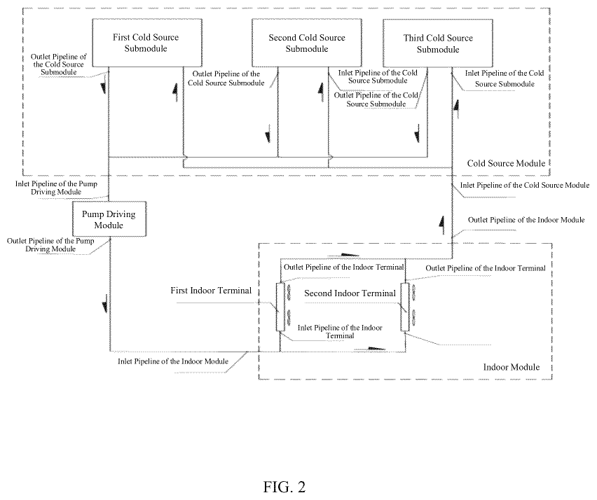

Embodiments of the present disclosure provide a multi-split air-conditioning system. As shown in FIG. 1 and FIG. 2, the multi-split air-conditioning system may include a cold source module, a pump driving module and an indoor module connected to a loop through a pipeline, where the cold source module includes a plurality of cold source submodules (three cold source submodules are shown in the figure). Outlet pipelines of the plurality of cold source submodules are connected to an inlet pipeline of the pump driving module. The indoor module includes a plurality of indoor terminals (two indoor terminals are shown in the figure). An outlet pipeline of the pump driving module is connected to inlet pipelines of the plurality of indoor terminals. Outlet pipelines of the plurality of indoor terminals converge and merge, and then are connected to an inlet pipeline of the cold source module.

In the embodiments of the present disclosure, outdoor parts of the air-conditioning system are modularized and divided into the pump driving module and the cold source module, where the cold source module may include a plurality of cold source submodules. The pump driving module may be arranged inside the cold source module or may be arranged outside the cold source module. The outlet pipeline of each cold source submodule may be separately connected to the inlet pipeline of the pump driving module, or the outlet pipelines of the plurality of cold source submodules may converge and merge, and then are connected to an inlet pipeline of the cold source module. Indoor parts of the air-conditioning system may include a set of or a plurality of sets of indoor terminals. Types of the indoor terminals may include room air conditioners, inter-row air conditioners, ventilation walls, backboards, and backboard ventilation walls, etc. The plurality of sets of indoor terminals (also known as multi-split terminals) may also be used in combination with a plurality of terminal types.

In one embodiment, each of the plurality of cold source submodules may include: a compressor, a first condenser, a second condenser, a heat exchanger, a first solenoid valve, a second solenoid valve, a third solenoid valve, and a compressor. An inlet of the compressor is connected to a first outlet pipeline of the heat exchanger, and an outlet of the compressor is connected to an inlet pipeline of the first condenser and/or an inlet pipeline of the second condenser. An outlet of the first condenser is connected to a first inlet pipeline of the heat exchanger, and an outlet of the second condenser is connected to the first inlet pipeline of the heat exchanger and/or the inlet pipeline of the pump driving module. The first solenoid valve is arranged on a second inlet pipeline of the heat exchanger or a second outlet pipeline of the heat exchanger. The second solenoid valve is arranged between the indoor module and the second condenser, and/or arranged between the second condenser and the pump driving module. The third solenoid valve is arranged between the compressor and the second condenser, and/or arranged between the second condenser and the heat exchanger. The second outlet pipeline of the heat exchanger is connected to the pump driving module.

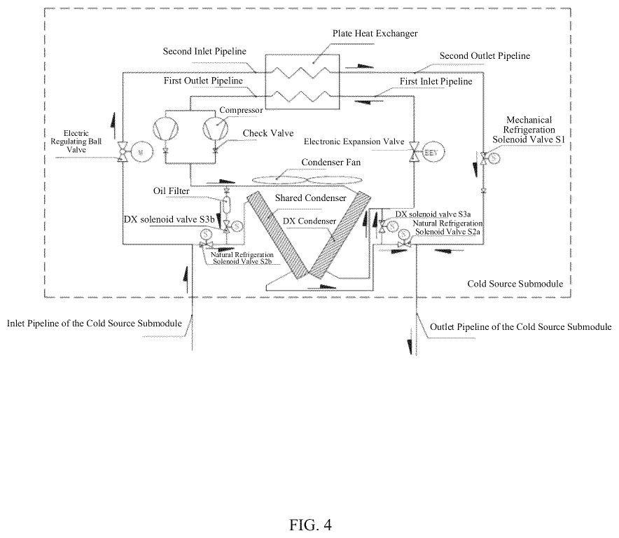

In one embodiment, as can be seen in FIG. 4, arrows may indicate flow directions of the refrigerant (gaseous or liquid) in the pipeline. The cold source submodule may include two sets of compressors connected in parallel. The heat exchanger may be a plate heat exchanger, refrigerant outlet and inlet positioned on a primary side of the heat exchanger may be referred to as a first outlet and a first inlet, and refrigerant outlet and inlet positioned on a secondary side may be referred to as a second outlet and a second inlet. The inlet of the compressor may be connected to the first outlet pipeline of the plate heat exchanger, and the outlet of the compressor may be divided into two paths, which are respectively connected to the inlet pipelines of the two condensers.

It is to be understood that the primary side of the air-conditioning system is a loop where the compressor is positioned, and the secondary side of the air-conditioning system is a loop where the indoor terminal is positioned.

In FIG. 4, a mechanical refrigeration solenoid valve S1 is arranged on the second outlet pipeline of the heat exchanger, a natural refrigeration solenoid valve S2a is arranged between the outlet pipeline of the second condenser and the inlet pipeline of the pump driving module, a natural refrigeration solenoid valve S2b is arranged between the outlet pipeline of the indoor module and the inlet pipeline of the second condenser, and a DX solenoid valve (direct expansion solenoid valve) S3a is arranged between the outlet pipeline of the second condenser and the first inlet pipeline of the heat exchanger, and a DX solenoid valve S3b is arranged between the outlet pipeline of the compressor and the inlet pipeline of the second condenser. In implementation, the refrigeration mode may be switched by controlling the mechanical refrigeration solenoid valve S1, the natural refrigeration solenoid valve S2a, the natural refrigeration solenoid valve S2b, the DX solenoid valve S3a, and the DX solenoid valve S3b. The refrigeration mode may include a mechanical refrigeration mode, a natural refrigeration mode, and a hybrid refrigeration mode. When the mechanical refrigeration mode or the hybrid refrigeration mode is used, energy regulation of the compressor may be carried out taking an evaporation pressure of the plate heat exchanger as a control target, but the present disclosure is not limit thereto.

In implementation, the compressor may be an oil-free centrifugal compressor or an oil-retaining scroll compressor.

It is worth mentioning that refrigeration capacity of the oil-free centrifugal compressor is smaller than that of the oil-retaining scroll compressor. When it is hot outdoors, there is a risk of surge and shutdown due to rise of a condensing pressure, which may have a negative effect on continuous refrigeration and thus cause interruption of service. Service life and reliability of the oil-free centrifugal compressor are lower. R134a (tetrafluoroethane) low-pressure refrigerant is commonly used in the centrifugal compressor, which may lead to greater efficiency loss and adversely affect energy efficiency in the case of longer connecting pipes between indoor units and outdoor units. Therefore, in a preferred embodiment, the oil-retaining scroll compressor may be used.

In implementation, the oil-retaining scroll compressor is resistant to high pressure, water-free in condensation, and can reduce occurrence of surge and effectively improve the reliability. Moreover, a new refrigerant R410a may be used as a high-pressure refrigerant with less pressure loss in the pipeline, which can adapt to longer connecting pipes between the indoor units and the outdoor units, thus effectively improving the energy efficiency of the system. Moreover, the present disclosure can reduce a lower limit of the refrigeration capacity of a single compressor to 50 kW. To adapt to different refrigeration capacity ranges, a plurality of compressors connected in parallel may be used. For example, the refrigeration capacity of the oil-retaining scroll compressor is around 50 kW, and the refrigeration capacity may be increased to around 100 kW by connecting two compressors in parallel. Of course, more compressors connected in parallel may also be used to achieve greater refrigeration capacity.

In implementation, to ensure that there is no oil on the secondary side, a check valve and an oil filter may also be connected to the outlet pipeline of the compressor. The check valve can prevent backflow of the refrigerant in the pipeline, and the oil filter can isolate a lubricating oil on the primary side and return the intercepted lubricating oil to a suction side (not shown in FIG. 4) of the compressor.

In one embodiment, the condenser of the multi-split air-conditioning system may be equipped with a double-layer coil tube to isolate a fluorine pump system (including a circulation loop of a refrigerant pump) and the compressor system (including a refrigerant circulation loop of the compressor). In this case, a condenser fan needs to withstand a higher air resistance, resulting in higher energy consumption. Moreover, higher costs of the double-layer coil tube leads to higher costs of a condenser device. Therefore, in a preferred embodiment, the condenser may use a single-layer coil tube, which can reduce the air resistance and the device costs compared to the double-layer coil tube.

In addition, an electric regulating ball valve may also be arranged on the second inlet pipeline of the heat exchanger. When the multi-split air-conditioning system adopts the hybrid refrigeration mode, the ratio of the mechanical refrigeration capacity to the natural refrigeration capacity may be adjusted by adjusting an opening degree of the electric regulating ball valve, to achieve stepless adjustment of the natural refrigeration and the mechanical refrigeration in the hybrid refrigeration mode. The opening degree of the electric regulating ball valve may be adjusted based on an evaporation temperature of upstream of a fluid reservoir in the pump driving module, which is not limited in the present disclosure.

Further, the pump driving module may include a refrigerant pump and the fluid reservoir. In some embodiments, the pump driving module may also include a check valve connected to the refrigerant pump through a pipeline to prevent backflow of the refrigerant.

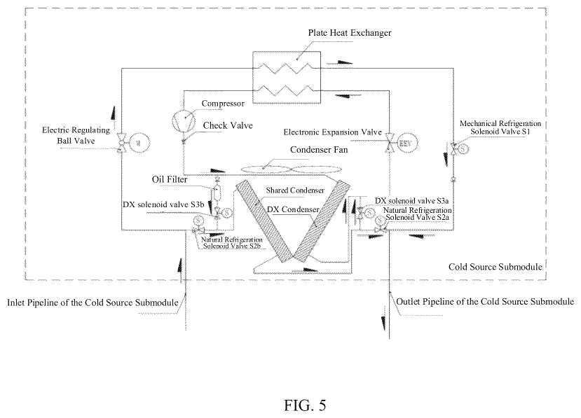

In another embodiment, as shown in FIG. 5, the cold source submodule may have only one compressor or one set of compressors, that is, in the embodiment shown in FIG. 4, the two sets of compressors connected in parallel are changed to a single compressor.

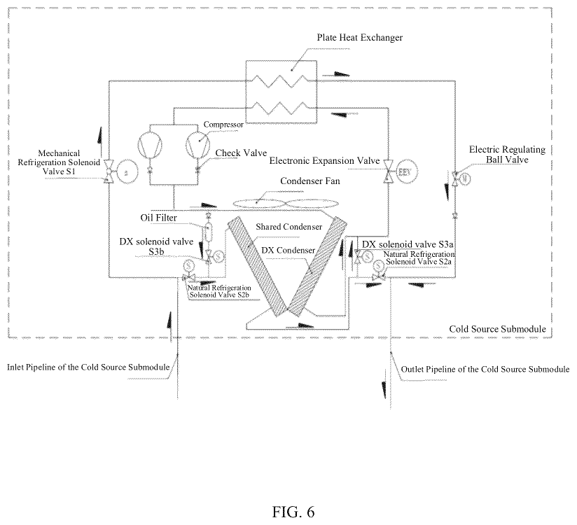

In yet another embodiment, as shown in FIG. 6, the electric regulating ball valve may be arranged on the second outlet pipeline of the heat exchanger, and the mechanical refrigeration solenoid valve S1 may be arranged on the second inlet pipeline of the heat exchanger.

In implementation, in the natural refrigeration mode, only the refrigerant pump and the condenser fan may be started, and the indoor module is refrigerated only by using a natural refrigeration source. In the mechanical refrigeration mode, the refrigerant pump, the compressor and the condenser fan may be started, and the indoor module is refrigerated only by using mechanical refrigeration. In the hybrid refrigeration mode, the refrigerant pump, the compressor and the condenser fan may be started, and the indoor module is refrigerated by using the natural refrigeration source and the mechanical refrigeration synchronously. On-off states of the solenoid valves and the electric regulating valve in different refrigeration modes may be seen in Table 1.

TABLE 1
On-Off States 1 under Different Refrigeration Modes

| | Mechanical | Natural | Natural | | | |
|---|---|---|---|---|---|---|
| | refrigeration | refrigeration | refrigeration | DX | DX | Electric |
| | solenoid | solenoid | solenoid | solenoid | solenoid | regulating |
| | valve S1 | valve S2a | valve S2b | valve S3a | valve S3b | ball valve |
| Natural | OFF | ON | ON | OFF | OFF | OFF |
| refrigeration | | | | | | |
| mode | | | | | | |
| Hybrid | ON | ON | ON | OFF | OFF | Adjustment |
| refrigeration | | | | | | of opening |
| mode | | | | | | degree |
| Mechanical | ON | OFF | OFF | ON | ON | Full open |
| refrigeration | | | | | | |
| mode | | | | | | |

In implementation, when the data center has higher demands for heat dissipation, the natural refrigeration mode may be adopted. In this case, the mechanical refrigeration solenoid valve S1, the DX solenoid valve S3a, the DX solenoid valve S3b and the electric regulating ball valve may be in the off state (OFF), while the natural refrigeration solenoid valve S2a and the natural refrigeration solenoid valve S2b may be in the on state (ON).

In this way, the refrigerant that has absorbed indoor heat of the data center computer room will flow through the outlet pipeline of the indoor air-conditioning system, the natural refrigeration solenoid valve S2b and a shared condenser in sequence. After being cooled down by the natural refrigeration source in the shared condenser, the refrigerant continues flowing through the natural refrigeration solenoid valve S2a, the pump driving module, and the inlet pipeline of the indoor air-conditioning system in sequence. In this case, the shared condenser is used as a condenser for a secondary-side fluorine pump system in the natural refrigeration mode.

When there is a larger amount of heat produced in the data center computer room and thus it is insufficient to meet the heat dissipation needs of the data center computer room in the natural refrigeration mode, the hybrid refrigeration mode or the mechanical refrigeration mode may be used.

When the hybrid refrigeration mode is used, the mechanical refrigeration solenoid valve S1, the natural refrigeration solenoid valve S2a and the natural refrigeration solenoid valve S2b may be in the on state, the DX solenoid valve S3a and the DX solenoid valve S3b may be in the off state, and the electric regulating ball valve may be in an open adjustment state and in any opening degree. By adjusting the opening degree of the electric regulating ball valve, flow capacity of the refrigerant flowing through the heat exchanger in a secondary-side loop may be adjusted.

In this way, when flowing through the outlet pipeline of the indoor air-conditioning system, the refrigerant may be divided into two paths. The first path of the refrigerant sequentially flows through the second inlet pipeline of the heat exchanger, the second outlet pipeline of the heat exchanger, and the pump driving module. The second path of the refrigerant sequentially flows through the natural refrigeration solenoid valve S2b, the shared condenser, the natural refrigeration solenoid valve S2a, and the pump driving module. The two paths of the refrigerant may converge at the pump driving module, flow through the inlet pipeline of the indoor air-conditioning system, enter the indoor terminal, and then return to the outlet pipeline of the indoor air-conditioning system to continue circulation flow.

Because the DX solenoid valve S3a and the DX solenoid valve S3b are in the off state, after being compressed by the compressor, the refrigerant may sequentially flow through the DX condenser (direct expansion condenser), the first inlet pipeline of the heat exchanger and the first outlet pipeline of the heat exchanger, and then return to the compressor to continue the circulation flow.

When the mechanical refrigeration mode is used, the mechanical refrigeration solenoid valve S1, the DX solenoid valve S3a and the DX solenoid valve S3b may be in the on state, the natural refrigeration solenoid valve S2a and the natural refrigeration solenoid valve S2b may be in the off state, and the electric regulating ball valve may be in the full open state.

In this way, after flowing through the outlet pipeline of the indoor air-conditioning system, the refrigerant in a secondary-side loop sequentially flows through the second inlet pipeline of the heat exchanger, the second outlet pipeline of the heat exchanger and the pump driving module, then enters the indoor terminal through the inlet pipeline of the indoor air-conditioning system, and then returns to the outlet pipeline of the indoor air-conditioning system to continue the circulation flow. After being compressed by the compressor, the refrigerant in a primary-side loop may be divided into two paths. The first path of the refrigerant sequentially flows through the shared condenser and the first inlet pipeline of the heat exchanger. The second path of the refrigerant sequentially flows through the DX condenser and the first inlet pipeline of the heat exchanger. The two paths of the refrigerant may converge at the first inlet pipeline of the heat exchanger, flow through the first outlet pipeline of the heat exchanger, and then return to the compressor to continue the circulation flow. In this case, the shared condenser is used as a condenser for the primary-side compressor system in the mechanical refrigeration mode.

It is to be understood that in the present disclosure, switching of the shared condenser used as the condenser for the fluorine pump system or the condenser for the compressor system is achieved by turning on or off the two sets of solenoid valves S2 and S3 which are mutually exclusive, such that the resistance of the condenser fan can be further reduced and the device costs can be reduced.

In implementation, an electronic expansion valve may also be connected to the first inlet pipeline of the heat exchanger. By adjusting the electronic expansion valve, liquid supply volume of the primary-side loop may be adjusted, resulting in a wider range of stepless adjustment and a faster response in the hybrid refrigeration mode. Of course, in some embodiments, the first inlet pipeline of the heat exchanger may not be equipped with the electronic expansion valve.

It is worth mentioning that electronic expansion valves may also be arranged at each indoor terminal of the indoor module. By adjusting each electronic expansion valve, the liquid supply volume flowing through each indoor terminal in the secondary-side loop may be adjusted. When the indoor module includes a plurality of sets of indoor terminals, adjustment parameters of the electronic expansion valves corresponding to different indoor terminals may be the same or may be different. In this way, the refrigeration capacity may be flexibly adjusted for different indoor terminals based on environment differences.

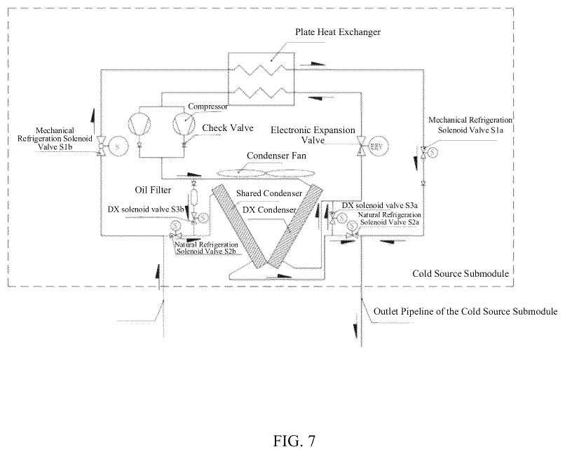

In another embodiment, as shown in FIG. 7, the mechanical refrigeration solenoid valve S1a may be arranged on the second outlet pipeline of the heat exchanger, and the mechanical refrigeration solenoid valve S1b may be arranged on the second inlet pipeline of the heat exchanger. That is, the electric regulating ball valve in the embodiment shown in FIG. 4 is replaced with the solenoid valve. In this embodiment, the on-off states of various valves in different refrigeration modes may be seen in Table 2.

TABLE 2
On-Off States 2 under Different Refrigeration Modes

| | Mechanical | Mechanical | Natural | Natural | | |
|---|---|---|---|---|---|---|
| | refrigeration | refrigeration | refrigeration | refrigeration | DX | DX |
| | solenoid | solenoid | solenoid | solenoid | solenoid | solenoid |
| | valve S1a | valve S1b | valve S2a | valve S2b | valve S3a | valve S3b |
| Natural | OFF | OFF | ON | ON | OFF | OFF |
| refrigeration | | | | | | |
| mode | | | | | | |
| Hybrid | ON | ON | ON | ON | OFF | OFF |
| refrigeration | | | | | | |
| mode | | | | | | |
| Mechanical | ON | ON | OFF | OFF | ON | ON |
| refrigeration | | | | | | |
| mode | | | | | | |

In implementation, reference may be made to the above embodiments for circulation paths of the refrigerant in various refrigeration modes, which are not to be described in the present disclosure.

Based on the same technical concept, the embodiments of the present disclosure also provide a method for air conditioning in a data center computer room, where the method is applied to the multi-split air-conditioning system of the above embodiments. This method includes:
switching a refrigeration mode by turning on or off the first solenoid valve, the second solenoid valve and the third solenoid valve, where the refrigeration mode includes a mechanical refrigeration mode, a natural refrigeration mode, and a hybrid refrigeration mode.

In one embodiment, the natural refrigeration mode is enabled when the first solenoid valve is turned off; the hybrid refrigeration mode is enabled when the first solenoid valve and the second solenoid valve are turned on and the third solenoid valve is turned off; and the mechanical refrigeration mode is enabled when the first solenoid valve and the third solenoid valve are turned on and the second solenoid valve is turned off.

In one embodiment, a ratio of mechanical refrigeration capacity to natural refrigeration capacity may be adjusted by adjusting an opening degree of the electric regulating ball valve.

By adopting the present disclosure, at least following technical effects can be achieved.

By splicing and combining the plurality of cold source submodules, it is easy to expand the air-conditioning system, which can achieve greater refrigeration demands. Moreover, the plurality of cold source submodules share the pump driving module, which can save space and improve energy efficiency of the air-conditioning system. Further, by turning on or off the first solenoid valve, the second solenoid valve and the third solenoid valve, flexible switching of the refrigeration modes may be achieved. On or off of the second solenoid valve and on or off of the third solenoid valve are mutually exclusive, which may allow the second condenser to be used as a condenser on a secondary side in the natural refrigeration mode and as a condenser on the primary-side compressor system in the mechanical refrigeration mode. This can effectively reduce a resistance of the condenser fan and reduce device costs. In the hybrid refrigeration mode, by adjusting the opening degree of the electric regulating ball valve, a flow rate of a refrigerant flowing through the heat exchanger in the secondary-side system in the mechanical refrigeration mode may be adjusted, that is, the ratio of the mechanical refrigeration capacity to the natural refrigeration capacity may be adjusted, to achieve stepless adjustment of the hybrid refrigeration where the natural refrigeration mode and the mechanical refrigeration mode coexist, thereby maximizing the energy efficiency of the entire air-conditioning system.

The embodiments described above are merely preferred embodiments of the present disclosure, and are not intended to limit the present disclosure. All modifications, equivalent substitutions and improvements made within the spirit and principles of the present disclosure shall fall within the protection scope of the present disclosure.

What is claimed is:

1. A multi-split air-conditioning system comprising a cold source module, a pump driving module and an indoor module connected to a loop through a pipeline; wherein
the cold source module comprises a plurality of cold source submodules; outlet pipelines of the plurality of cold source submodules are connected to an inlet pipeline of the pump driving module; and
the indoor module comprises a plurality of indoor terminals; an outlet pipeline of the pump driving module is connected to inlet pipelines of the plurality of indoor terminals; and outlet pipelines of the plurality of indoor terminals converge and merge, and then are connected to an inlet pipeline of the cold source module.

2. The multi-split air-conditioning system as claimed in claim 1, wherein the outlet pipelines of the plurality of cold source submodules converge and merge, and then are connected to the inlet pipeline of the pump driving module.

3. The multi-split air-conditioning system as claimed in claim 1, wherein each of the plurality of cold source submodules comprises: a compressor, a first condenser, a second condenser, a heat exchanger, a first solenoid valve, a second solenoid valve, a third solenoid valve, and a compressor;
an inlet of the compressor is connected to a first outlet pipeline of the heat exchanger, and an outlet of the compressor is connected to an inlet pipeline of the first condenser and/or an inlet pipeline of the second condenser;
an outlet of the first condenser is connected to a first inlet pipeline of the heat exchanger, and an outlet of the second condenser is connected to the first inlet pipeline of the heat exchanger and/or the inlet pipeline of the pump driving module;
the first solenoid valve is arranged on a second inlet pipeline of the heat exchanger or a second outlet pipeline of the heat exchanger;
the second solenoid valve is arranged between the indoor module and the second condenser, and/or arranged between the second condenser and the pump driving module;
the third solenoid valve is arranged between the compressor and the second condenser, and/or arranged between the second condenser and the heat exchanger; and
the second outlet pipeline of the heat exchanger is connected to the pump driving module.

4. The multi-split air-conditioning system as claimed in claim 3, wherein an electric regulating ball valve is connected to a second inlet pipeline of the heat exchanger or a second outlet pipeline of the heat exchanger.

5. The multi-split air-conditioning system as claimed in claim 3, wherein an electronic expansion valve is connected to a first inlet pipeline of the heat exchanger.

6. The multi-split air-conditioning system as claimed in claim 2, wherein the pump driving module comprises a refrigerant pump and a fluid reservoir.

7. The multi-split air-conditioning system as claimed in claim 6, wherein the pump driving module further comprises a check valve connected to the refrigerant pump through a pipeline.

8. A method for air conditioning in a data center computer room, wherein the method is applied to a multi-split air-conditioning system comprising a cold source module, a pump driving module and an indoor module connected to a loop through a pipeline; wherein
the cold source module comprises a plurality of cold source submodules; outlet pipelines of the plurality of cold source submodules are connected to an inlet pipeline of the pump driving module; and
the indoor module comprises a plurality of indoor terminals; an outlet pipeline of the pump driving module is connected to inlet pipelines of the plurality of indoor terminals; and outlet pipelines of the plurality of indoor terminals converge and merge, and then are connected to an inlet pipeline of the cold source module; the method comprising:
switching a refrigeration mode by turning on or off the first solenoid valve, the second solenoid valve and the third solenoid valve, wherein the refrigeration mode comprises a mechanical refrigeration mode, a natural refrigeration mode, and a hybrid refrigeration mode.

9. The method for air conditioning as claimed in claim 8, wherein the outlet pipelines of the plurality of cold source submodules converge and merge, and then are connected to the inlet pipeline of the pump driving module.

10. The method for air conditioning as claimed in claim 8, wherein each of the plurality of cold source submodules comprises: a compressor, a first condenser, a second condenser, a heat exchanger, a first solenoid valve, a second solenoid valve, a third solenoid valve, and a compressor;
an inlet of the compressor is connected to a first outlet pipeline of the heat exchanger, and an outlet of the compressor is connected to an inlet pipeline of the first condenser and/or an inlet pipeline of the second condenser;
an outlet of the first condenser is connected to a first inlet pipeline of the heat exchanger, and an outlet of the second condenser is connected to the first inlet pipeline of the heat exchanger and/or the inlet pipeline of the pump driving module;
the first solenoid valve is arranged on a second inlet pipeline of the heat exchanger or a second outlet pipeline of the heat exchanger;
the second solenoid valve is arranged between the indoor module and the second condenser, and/or arranged between the second condenser and the pump driving module;
the third solenoid valve is arranged between the compressor and the second condenser, and/or arranged between the second condenser and the heat exchanger; and
the second outlet pipeline of the heat exchanger is connected to the pump driving module.

11. The method for air conditioning as claimed in claim 10, wherein an electric regulating ball valve is connected to a second inlet pipeline of the heat exchanger or a second outlet pipeline of the heat exchanger.

12. The method for air conditioning as claimed in claim 10, wherein an electronic expansion valve is connected to a first inlet pipeline of the heat exchanger.

13. The method for air conditioning as claimed in claim 9, wherein the pump driving module comprises a refrigerant pump and a fluid reservoir.

14. The method for air conditioning as claimed in claim 13, wherein the pump driving module further comprises a check valve connected to the refrigerant pump through a pipeline.

15. The method for air conditioning as claimed in claim 8, wherein
the natural refrigeration mode is enabled when the first solenoid valve is turned off;
the hybrid refrigeration mode is enabled when the first solenoid valve and the second solenoid valve are turned on and the third solenoid valve is turned off; and
the mechanical refrigeration mode is enabled when the first solenoid valve and the third solenoid valve are turned on and the second solenoid valve is turned off.

16. The method for air conditioning as claimed in claim 15, wherein a ratio of mechanical refrigeration capacity to natural refrigeration capacity is adjusted by adjusting an opening degree of the electric regulating ball valve.
